(19) United States
(12) Patent Application Publication
(10) Pub. No.: US 2025/0210938 A1
(43) Pub. Date: Jun. 26, 2025

(54) TUNABLE LASER

(71) Applicant: SMART PHOTONICS HOLDING B.V., Eindhoven (NL)

(72) Inventor: Stefanos ANDREOU, Eindhoven (NL)

(21) Appl. No.: 19/060,027

(22) Filed: Feb. 21, 2025

Related U.S. Application Data
(63) Continuation of application No. PCT/EP2023/073857, filed on Aug. 30, 2023.

(30) Foreign Application Priority Data
Aug. 31, 2022 (GB) 2212667.6

(51) Int. Cl. H01S 5/06; H01S 5/062

(52) U.S. Cl. CPC H01S 5/0612; H01S 5/062

(57) ABSTRACT

A tunable laser comprising a first wafer, a second wafer, and an optical cavity. The first wafer is of a first semiconductor material. The first wafer supports an optical amplifier and an electro-optically tunable optical filter. The second wafer is of a second material different from the first semiconductor material. The second wafer supports a thermally tunable optical filter. The optical cavity comprises the optical amplifier, the electro-optically tunable optical filter, and the thermally tunable optical filter.

### CROSS REFERENCE TO RELATED APPLICATIONS

This application is a continuation under 35 U.S.C. § 120 of International Application No. PCT/EP2023/073857, filed Aug. 30, 2023 which claims priority to United Kingdom Application No. GB 2212667.6, filed Aug. 31, 2022 under 35 U.S.C. § 119 (a). Each of the above-referenced patent applications is incorporated by reference in its entirety.

### BACKGROUND

Tunable lasers are used to produce light of at least one of tunable wavelength or tunable power. Tuning of the wavelength and/or power to be output by the tunable laser may be for communications systems and/or optical systems. It is desirable to provide an improved tunable laser.

### BRIEF DESCRIPTION OF THE DRAWINGS

FIGS. 1 to 4 each show schematically a plan view of a tunable laser in accordance with examples.

FIG. 5 shows schematically a plan view of parts of a photonic integrated circuit (PIC) in accordance with examples.

FIG. 6 shows schematically a plan view of a device in accordance with examples.

FIGS. 7 and 8 each schematically show a method of manufacturing a tunable laser in accordance with examples.

### DETAILED DESCRIPTION

In examples to be described, a tunable laser comprises a first wafer of a first semiconductor material. The first wafer supports an optical amplifier and an electro-optically tunable optical filter. The tunable laser further comprises a second wafer of a second material different from the first semiconductor material. The second wafer supports a thermally tunable optical filter. The tunable laser comprises an optical cavity which comprises the optical amplifier, the electro-optically tunable optical filter, and the thermally tunable optical filter. The electro-optically tunable optical filter and the thermally tunable optical filter in combination are configured for the tuning of at least one of the power or the wavelength of light to be output by the tunable laser. In so doing, the tunable laser can, for example, provide an output of a chosen wavelength and/or power. The output of the tunable laser is, for example, for photonic devices or systems such as those for medical imaging, spectroscopy, telecommunications, optical data transmission, random number generation, and light detection and ranging (LIDAR).

At least one of the electro-optically tunable optical filter or the thermally tunable optical filter may be configured to suppress undesired wavelengths of light, so the output of the tunable laser is switchable between different wavelengths. Spectral filtering of the output of the tunable laser, for example, is desirable for applications such as communications, spectroscopy, or imaging. This can reduce the need for a further optical component for wavelength tuning, which may simplify manufacture of a device comprising the tunable laser, reduce the footprint of and/or reduce the cost of producing a device comprising the laser.

At least one of the electro-optically tunable optical filter or the thermally tunable optical filter may be configured for modulation of the power of the output of the tunable laser; in such examples electrical signals may be directly converted into optical signals. In some examples, modulation of the power of the output of the tunable laser in response to an electrical signal input to the electro-tunable optical filter is desirable for applications such as communications. This can reduce the need for a further optical component for electro-optic modulation, which for example simplifies manufacture of a device comprising the tunable laser, reduces the footprint of and/or reduces the cost of producing a device comprising the laser.

An output of the tunable laser in some examples has a single wavelength intensity-peak that is tunable over a range. The range is for example within the range of 10 nanometres to 1 millimetre. A single intensity-peak and/or wavelength tuning may be achieved by the superposition of the thermally tunable optical filter and the electro-optically tunable optical filter. In some examples, the light amplified by the optical amplifier is for amplifying infrared; in some such examples, the wavelength of the output of the tunable laser is tunable between 1530 nanometres and 1565 nanometres. Such wavelengths may be used for telecommunication applications.

A tunable optical filter is an optical element tunable to adjust its output spectrum (for example, the frequency-spectrum of the output). A tunable optical filter may comprise at least one of a tunable resonator or an interferometer.

An electro-optically tunable optical filter is a tunable optical filter. The output spectrum of an electro-optically tunable filter is tunable by an electro-optic effect such as the Pockels effect or the Kerr effect, with the refractive index of a material dependent on the electric field applied to it. The electro-optically tunable optical filter may be a diode and/or reversed biased. Consequently, an electro-optically tunable optical filter requires a material that presents an electro-optic effect such as indium phosphide (InP), indium gallium arsenide phosphide (InGaAsP), aluminium gallium arsenide (AlGaAs), lithium niobate (LiNbO3), or beta barium borate (BBO).

A thermally tunable optical filter is a tunable optical filter. The output spectrum of a thermally tunable optical filter is tunable by the thermal-optic effect. The thermo-optic effect causes the refractive index of a material to be dependent on the temperature of the material. Consequently, a thermally tunable optical filter requires a material that presents a thermo-optic effect and is mechanically resilient to temperature changes, such as silicon (Si) or silicon nitride (SiN).

The first semiconductor material is different to the second material. In some such examples the first semiconductor material presents an electro-optic effect and the second material presents a thermo-optic effect. The use of such materials may increase the design freedoms within the tunable laser, and in some such examples the tunable laser comprises electro-optic components, thermo-optic components, an electro-optically tunable optical filter, and a thermally tunable optical filter. It was found to be desirable to use a material such as a material with an electro-optic effect for the electro-optically tunable optical filter, and a different material such as a material with a thermo-optic effect for the thermally tunable optical filter. In some examples the first semiconductor material is InP and the second material is SiN. Note that whilst the first semiconductor material might in some examples also present a thermo-optic effect to some extent and/or the second material might in some examples also present an electro-optic effect to some extent, the tunable laser in examples herein is configured not to utilise these effects for tuning. Instead, the laser is configured to use the electro-optic effect of the first semiconductor material and the thermo-optic effect of the second material.

Terms and features used herein, such as a waveguide, tunable resonator and interferometer are described in more detail later. But it is useful here to elaborate on a wafer referred to herein: a wafer may also be referred to as a chip, a slice, a substrate or a layer. A wafer is, e.g., a generally planar or relatively thin portion of material, and in some examples is crystalline. A wafer may be a disc or part of a disc of crystalline Si for use in a semiconductor fabrication plant, and in some such examples is a 125 gram, 300 millimetre diameter disc. A wafer may alternatively be a disc or part of a disc of crystalline InP for use in a semiconductor fabrication plant, and in some such examples is a 25 millimetre, 51 millimetre, 76 millimetre, 100 millimetre, 200 millimetre or 300 millimetre diameter disc.

A general introduction to examples herein relating to a tunable laser is now given with reference to FIG. 1. FIG. 1 schematically shows a plan view of a tunable laser 100. The tunable laser 100 comprises a first wafer 102 of a first semiconductor material. The first wafer 102 supports or comprises an optical amplifier 104 and an electro-optically tunable optical filter 106. The tunable laser 100 further comprises a second wafer 110 of a second material. The second material is different from the first semiconductor material. The second wafer 110 supports or comprises a thermally tunable optical filter 108. The second wafer 110 is optically connected to the first wafer 102. The tunable laser 100 comprises an optical cavity 120. The optical cavity comprises: the optical amplifier 104, the electro-optically tunable optical filter 106, and the thermally tunable optical filter 108. Other sequences of the elements configured as the optical cavity to the sequence shown are envisaged. The first wafer 102 is in contact with and abuts the second wafer 110. In other examples not shown the first wafer is optically connected to the second wafer and not in contact with the second wafer. In various examples the first wafer is on the second wafer; the second wafer is on the first wafer; the first wafer supports the second wafer; and/or the second wafer supports the first wafer. In FIG. 1 dashed lines are used to indicate where the first wafer or the second wafer may extend laterally beyond the illustration (for example, as part of a PIC).

A description of further examples herein relating to a tunable laser is now given with reference to FIG. 2. In some examples, the optical cavity is configured as a ring optical cavity, for example, the components in the cavity are optically connected in series to form a ring. Such a tunable laser may be referred to as a tunable ring laser. A tunable ring laser may be used for a ring laser gyroscope or for apparatus for gravitational waves, relativistic effects, or quantum-electrodynamic effects.

FIG. 2 schematically shows a plan view of a tunable laser 200 of examples described herein. Where a feature in relation to FIG. 2 corresponds with a feature described using FIG. 1, a reference numeral is used which is 100 greater than the corresponding reference numeral used for FIG. 1 (e.g., 102 in FIG. 1 is 202 in FIG. 2); corresponding descriptions for such features apply here also. Similarly as for FIG. 1, dashed lines are used to indicate where the first wafer or the second wafer may extend laterally beyond the illustration (for example, as part of a PIC).

The optical cavity 220 is configured as a ring optical cavity 220, though other ring optical cavity configurations are envisaged than those shown. The tunable laser 200 comprises a first wafer 202 supporting and/or comprising an optical amplifier 204 optically connected to an electro-optically tunable optical filter 206 by a first waveguide 215. The tunable laser 200 further comprises a second wafer 210 supporting and/or comprising a thermally tunable optical filter 208 optically connected to the optical amplifier 204 by a second waveguide 213. The second wafer 210 is optically connected to the first wafer 202 by the second waveguide 213. The thermally tunable optical filter 208 is optically connected to the electro-optically tunable optical filter 206 by a third waveguide 211 to form the ring optical cavity 220. The ring optical cavity 220 comprises the optical amplifier 204, the electro-optically tunable optical filter 206, and the thermally tunable optical filter 208. Other sequences of the elements configured as the ring optical cavity to the sequence shown are envisaged.

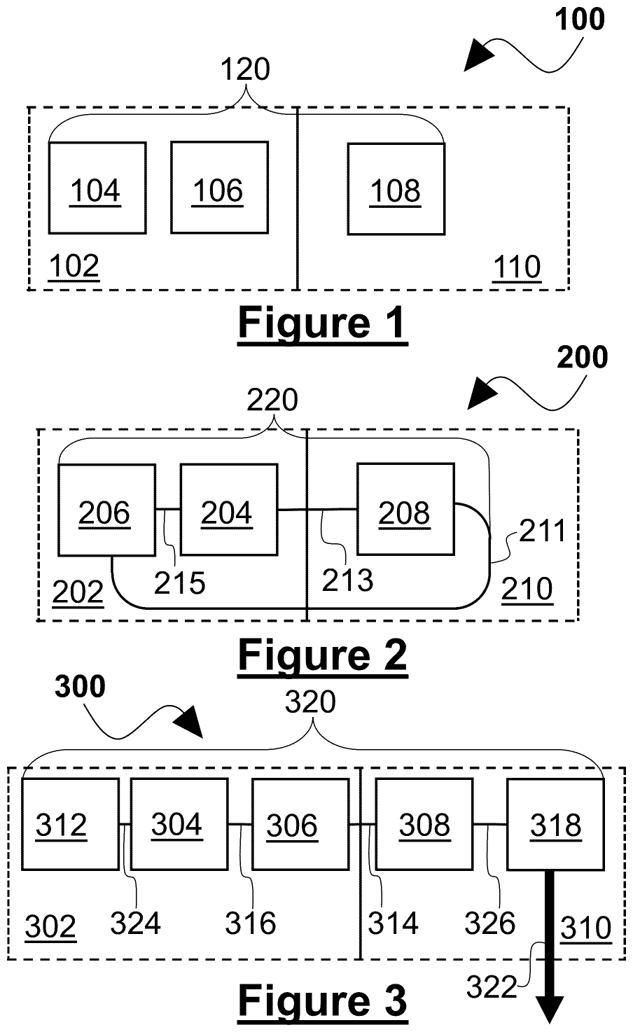

A description of further examples herein relating to a tunable laser is now given with reference to FIG. 3. In some examples, the optical cavity is a linear optical cavity. The components in a linear optical cavity are optically connected in series with a reflector, partial reflector, resonator and/or an interferometer at each terminus of the linear optical cavity. Such a tunable laser may be referred to as a tunable linear laser or a linear tunable laser. A linear optical cavity for example reduces the footprint of the linear tunable laser compared to other cavity configurations such as a ring cavity and/or achieves more efficient filtering of the lasing mode.

FIG. 3 schematically shows a plan view of a tunable laser 300 of examples described herein with the optical cavity 320 configured as a linear optical cavity 320, though other configurations of the optical cavity are envisaged than as shown. Other sequences of the elements configured as the optical cavity to the sequence shown are envisaged. Where a feature in relation to FIG. 3 corresponds with a feature described using FIG. 1, a reference numeral is used which is 200 greater than the corresponding reference numeral used for FIG. 1 (e.g., 102 in FIG. 1 is 302 in FIG. 3); corresponding descriptions for such features apply here also. Similarly as for FIG. 1 and FIG. 2, dashed lines are used to indicate where the first wafer or the second wafer may extend laterally beyond the illustration (for example, as part of a PIC).

The tunable laser 300 comprises a first wafer 302 supporting and/or comprising an optical amplifier 304 optically connected to an electro-optically tunable optical filter 306 by a second waveguide 316. The first wafer 302 also supports and/or comprises a resonator 312. In other examples, the resonator is at least one of: a reflector, a partial reflector, or an interferometer. The resonator 312 is optically connected to the optical amplifier 304 by a fourth waveguide 324. The tunable laser 300 further comprises a second wafer 310 supporting and/or comprising a thermally tunable optical filter 308 optically connected to the electro-optically tunable optical filter 306 by a first waveguide 314. The second wafer 310 is optically connected to the first wafer 302 by the first waveguide 314. The second wafer 302 also supports and/or comprises a multimode interferometer (MMI) 318. In other examples, the MMI 318 is at least one of: a reflector, a partial reflector, a resonator or another configuration of an interferometer. The MMI 318 is optically connected to the thermally tunable optical filter 308 by a third waveguide 326. The MMI 318 has an output 322 that is the output of the tunable laser 300. The linear optical cavity 320 comprises the resonator 312, the optical amplifier 304, the electro-optically tunable optical filter 306, the thermally tunable optical filter 308, and the MMI 318.

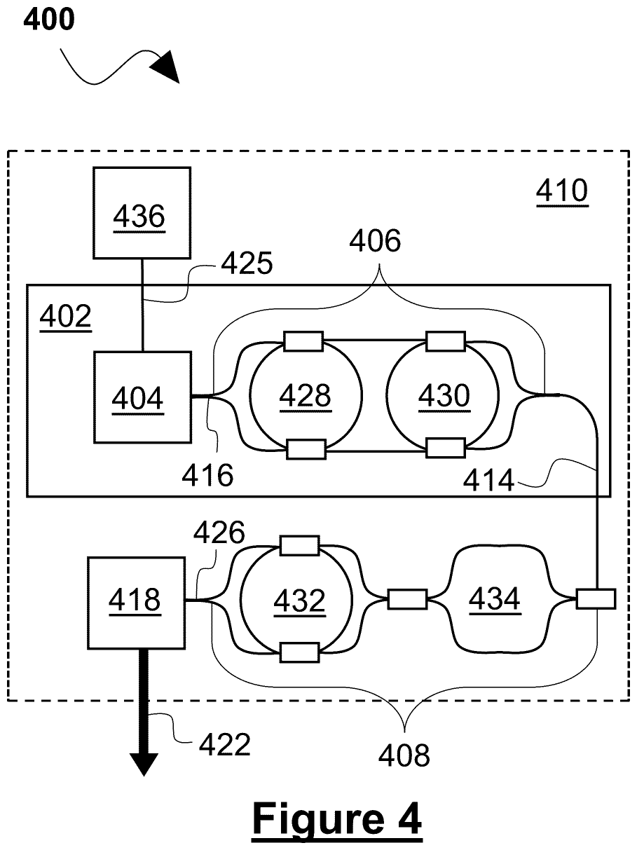

A description of further examples herein relating to a tunable laser is now given with reference to FIG. 4. FIG. 4 schematically shows a plan view of a tunable laser 400 of examples described herein. Where a feature in relation to FIG. 4 corresponds with a feature described using FIG. 3, a reference numeral is used which is 100 greater than the corresponding reference numeral used for FIG. 3 (e.g., 302 in FIG. 3 is 402 in FIG. 4); corresponding descriptions for such features apply here also. Similarly as for FIGS. 1 to 3, dashed lines are used to indicate where the second wafer may extend laterally beyond the illustration (for example, as part of a PIC). The first wafer 402 is supported by the second wafer 410 and is on the second wafer 410. In other examples not shown, the second wafer is supported by and/or on the first wafer. The tunable laser 400 comprises a first wafer 402 supporting and/or comprising an optical amplifier 404 optically connected to an electro-optically tunable optical filter 406 by a second waveguide 416. The electro-optically tunable optical filter 406 comprises a tunable ring resonator 428 and 430. The tunable ring resonators 428 and 430 of the electro-optically tunable optical filter 406 are optically connected by at least one MMI and/or at least one waveguide. In other examples not shown the electro-optically tunable optical filter comprises an interferometer. The tunable laser 400 further comprises a second wafer 410 supporting and/or comprising a thermally tunable optical filter 408 optically connected to the electro-optically tunable optical filter 406 by a first waveguide 414. The thermally tunable optical filter 408 comprises a tunable ring resonator 432 and an interferometer 434. In other examples not shown, the thermally tunable optical filter comprises a plurality of tunable ring resonators. The tunable ring resonator 432 is optically connected to the interferometer 434 by at least one MMI and/or at least one waveguide. In various examples at least one of: the electro-optically tunable optical filter, or the thermally tunable optical filter, comprises a tunable resonator. The second wafer 402 supports and/or comprises a first MMI 418 and a second MMI 436. The first MMI 418 is optically connected to the thermally tunable optical filter 408 by a third waveguide 426. The second MMI 436 is optically connected to the optical amplifier 404 by a third waveguide 426. The first MMI 418 has an output 422 that is the output of the tunable laser 400. The second wafer 410 is optically connected to the first wafer 402 by a first waveguide 414 and a fourth waveguide 425. The tunable laser 400 comprises an optical cavity comprising: the optical amplifier 404, the electro-optically tunable optical filter 406, the thermally tunable optical filter 408, the first MMI 418 and the second MMI 436.

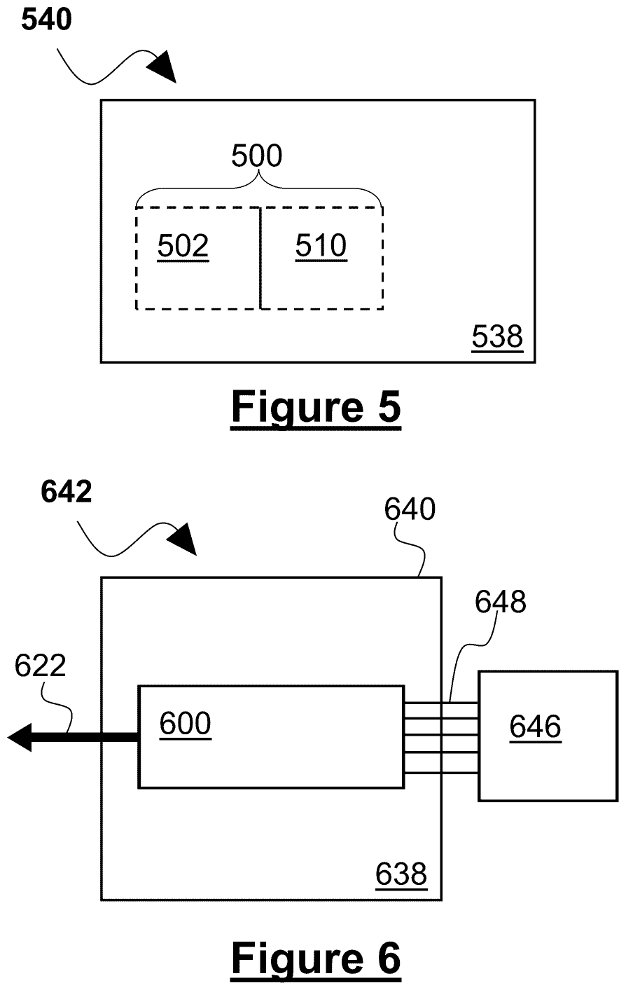

A description of examples herein relating to a PIC is now given with reference to FIG. 5. The tunable laser may be configured for use in, or integration into, a generic photonic platform. In some examples, at least one of the first wafer or the second wafer is a substrate for a PIC; in other examples the first wafer and the second wafer are supported by and/or on a substrate for a PIC. A generic photonic platform uses standardised processes for fabricating photonic components and/or standardised photonic components for the resulting PICs. Integration into a generic photonic platform may simplify combination of the tunable laser with one or more components of the PIC. The tunable laser may be integrated into a generic platform; in some such examples the fabrication of the PIC is simpler, cheaper, quicker and have a broad range of applications. A PIC integrates a plurality of photonic functions, for example a laser or a photodiode, though other photonic functions are envisaged. In the examples shown schematically and in plan view by FIG. 5, a photonic integrated circuit 540 comprises the tunable laser 500 of examples described herein. Where a feature in relation to FIG. 5 corresponds with a feature described using FIG. 1, a reference numeral is used which is 400 greater than the corresponding reference numeral used for FIG. 1 (e.g., 102 in FIG. 1 is 502 in FIG. 5); corresponding descriptions for such features apply here also.

The PIC 540 comprises a tunable laser 500 supported by and on a substrate 538. The first wafer 502 and the second wafer 510 of the tunable laser 500 are on a substrate 538, and the substrate 538 is for a PIC 540. In other examples not shown, the substrate is not for a PIC, but for example the substrate is a printed circuit board (PCB), integrated circuit (IC) or a support for the tunable laser 500. A support for the tunable laser may increase the thermal and/or mechanical stability of the laser, which may increase performance of the tunable laser. In some examples, the tunable laser is integrated into a PIC. Dashed lines are used to indicate that in some examples either the first wafer or the second is part of the substrate. In some examples the substrate is of a third material, in some such examples either the first semiconductor material or the second material is the same as the third material.

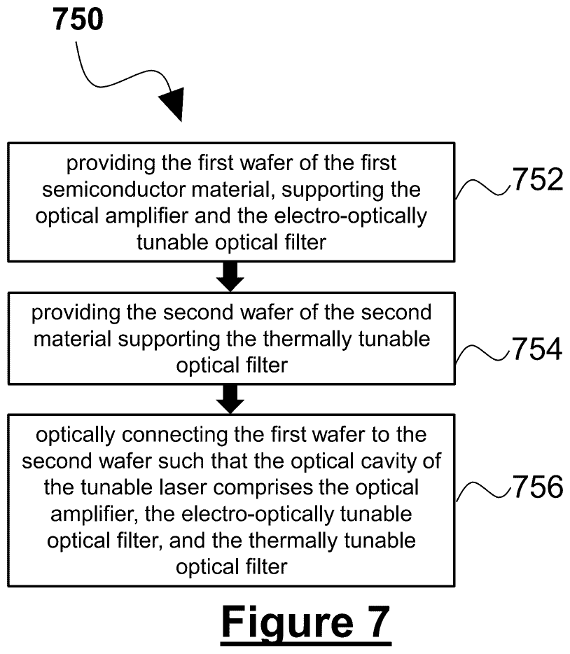

A description of examples herein relating to a device is now given with reference to FIG. 6. Some examples herein, relate to a device comprising the PIC described herein. FIG. 6 schematically shows a plan view of at least part of a photonic device 642 comprising a PIC 640 comprising a tunable laser 600. Where a feature in relation to FIG. 6 corresponds with a feature described using FIG. 3 or 5, a reference numeral is used which is 300 or 100 greater respectively than the corresponding reference numeral used for FIG. 3 or FIG. 5 respectively (e.g., 302 in FIG. 3 is 602 in FIGS. 6, and 538 in FIG. 5 is 638 in FIG. 6); corresponding descriptions for such features apply here also.

The photonic device 642 comprises an output for light 622, for example for light emitting applications such as LIDAR. In other examples not shown the photonic device does not emit light, for example, for a random number generator photonic device no or less of the light emitted within the PIC leaves the PIC. The photonic device comprises a controller 646 electrically connected to the tunable laser 600 by electrical connections 648. In some examples, the controller 630 is for at least one of modulation of the power of the output 622 of the tunable laser 600, or modulation of the peak wavelength of the output 622. The controller 646 may be a control circuit, an IC, a processor, a microcontroller, or a computer. Other controllers are envisaged. In some examples, the PIC 640 comprises electrical circuitry and/or the components of the PIC 640 are externally controlled by appropriate electrical connections to electrodes or other electrical contacts on the PIC 640.

A description of examples of a method 750 of manufacturing the tunable laser 100 in accordance with examples described herein (such as the examples of FIG. 1) is now given with reference to FIG. 7 and FIG. 1 (FIG. 1 is used as an example, the method 750 may also apply to any examples of FIGS. 2 to 4). FIG. 7 schematically shows the method 750 comprising providing 752 the first wafer 102 of the first semiconductor material. The first wafer 102 supports the optical amplifier 104 and the electro-optically tunable optical filter 106. Providing 752 the first wafer 102 may comprise using a pre-assembled, pre-formed, and/or pre-processed wafer. In other examples providing 752 the first wafer includes assembling, processing and/or forming the first wafer 102. The method then comprises providing 754 the second wafer 110 of the second material different from the first semiconductor material. The second wafer 110 supports the thermally tunable optical filter 108. Providing 754 the second wafer 110 may comprise using a pre-assembled, pre-formed, and/or pre-processed wafer. In other examples providing 754 the second wafer includes assembling, processing and/or forming the first wafer. The method then comprises optically connecting 756 the first wafer 102 to the second wafer 110 such that an optical cavity 120 of the tunable laser 110 comprises the optical amplifier 104, the electro-optically tunable optical filter 106, and the thermally tunable optical filter 108. Such a method may be referred to as hybrid integration. The first wafer and the second wafer may be optically connected by mechanically connecting the first wafer 102 and the second wafer 104. In other examples the first wafer and the second wafer are optically connected as well as not mechanically connected and/or in contact. Mechanically connecting the first wafer 102 and the second wafer 110 may comprise bonding and/or attaching the first wafer 102 directly or indirectly to the second wafer 110. In other examples mechanically connecting the first wafer 102 to the second wafer 110 comprises attaching and/or bonding both the first wafer 102 and the second wafer 110 to a substrate, or in other examples or micro-transfer printing the first wafer on the second wafer, or micro-transfer printing at least one of the first wafer or the second wafer on a substrate. In further examples mechanically connecting the first wafer 102 and the second wafer 110 comprises abutting the first wafer 102 and the second wafer 110. Other mechanical connections between the first wafer 102 and the second wafer 110 are envisaged. Hybrid integration is, for example, when a tunable laser 100, PIC or a photonic device is manufactured by providing the first wafer 102 supporting photonic components and the second wafer 110 supporting photonic components, and then optically connecting the first wafer 102 and the second wafer 110 to each other. Hybrid integration may comprise processes and/or techniques to provide the first wafer 102 or photonic components supported by the first wafer 102 that are not compatible with the second wafer 110 or photonic components supported by the second wafer. Hybrid integration may comprise processes and/or techniques to provide the second wafer 110 or photonic components supported by the second wafer 110 that are not compatible with the first wafer 102 or photonic components supported by the first wafer 102. In some examples of hybrid integration providing 752 the first wafer 102 supporting the optical amplifier 104 and the electro-optically tunable optical filter 106 and providing 754 the second wafer 110 supporting the thermally tunable optical filter 108 are done at different times, by different parties or at geographically different locations. Some examples herein relate to a method of manufacturing a PIC comprising the method 750 of manufacturing a tunable laser 100 as described herein. Further, some examples herein relate to a method of manufacturing a device comprising the method 750 of manufacturing a tunable laser 100 as described herein or the method of manufacturing a PIC described herein.

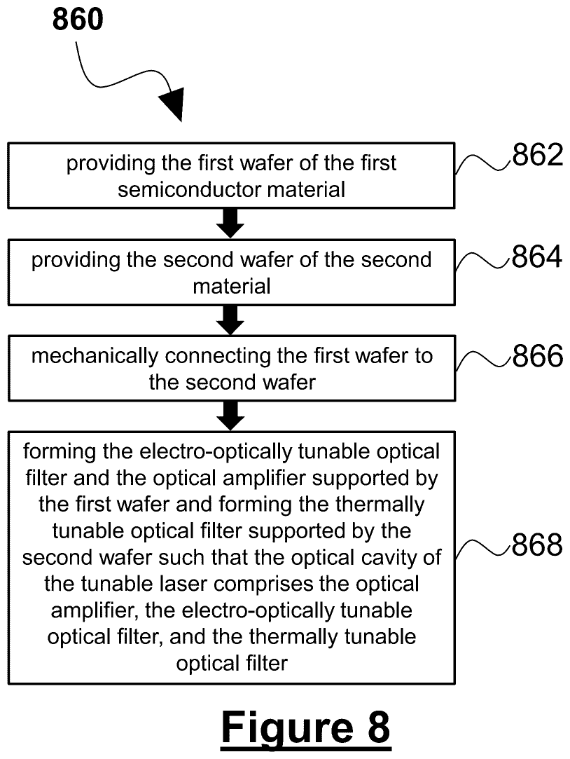

A description of further examples of a method 860 of manufacturing the tunable laser 100 in accordance with examples described herein (such as the examples of FIG. 1) is now given with reference to FIG. 8 and FIG. 1 (FIG. 1 is used as an example, the method 750 may also apply to any examples of FIGS. 2 to 4). FIG. 8 schematically shows a method 860 comprising providing 862 the first wafer 102 of the first semiconductor material. Providing 862 the first wafer 102 may comprise using a pre-assembled, pre-formed, and/or pre-processed wafer. In other examples providing 862 the first wafer 102 includes assembling, processing and/or forming the first wafer 102. The method then comprises providing 864 the second wafer 110 of the second material. Providing 864 the second wafer 110 may comprise using a pre-assembled, pre-formed, and/or pre-processed wafer. In other examples providing 864 the second wafer 110 includes assembling, processing and/or forming the second wafer 110. Then the method comprises mechanically connecting 866 the first wafer 102 to the second wafer 110. Similarly to as described for FIG. 7, mechanically connecting the first wafer 102 and the second wafer 110 may comprise bonding and/or attaching the first wafer 102 directly to the second wafer 110. In other examples mechanically connecting the first wafer 102 to the second wafer 110 comprises attaching and/or bonding both the first wafer 102 and the second wafer 110 to a substrate. In further examples mechanically connecting the first wafer 102 and the second wafer 110 comprises abutting the first wafer 102 and the second wafer 110. Other mechanical connections between the first wafer 102 and the second wafer 110 are envisaged. Next, the method comprises forming 868 the electro-optically tunable optical filter 106 and the optical amplifier 104 on the first wafer 102 and forming the thermally tunable optical filter 108 on the second wafer 110 such that the optical cavity 120 of the tunable laser 100 comprises the optical amplifier 104, the electro-optically tunable optical filter 104 and the thermally tunable optical filter 108. The optical cavity 120 may be configured by optically connecting the first wafer 102 and the second wafer 110 to each other. Heterogeneous integration, for example, when a tunable laser 100, PIC or a photonic device is manufactured by mechanically connecting the first wafer 102 and the second wafer 110 and then using processes and/or techniques to provide the desired photonic components supported by the first wafer 102 and/or the second wafer 110. Heterogeneous integration may comprise providing the tunable laser 110, PIC, or photonic device using a single die and/or a generic platform. Heterogeneous integration may reduce the foundry time required to produce the tunable laser and/or the footprint of the tunable laser 100. Some examples herein relate to a method of manufacturing a PIC comprising the method 860 of manufacturing a tunable laser 100 as described herein. Further, some examples herein relate to a method of manufacturing a device comprising the method 860 of manufacturing a tunable laser 100 as described herein or the method of manufacturing a PIC described herein.

The example methods described herein may comprise providing the controller as previously described. The controller is, for example, configured for at least one of modulation of the power of the output of the tunable laser, or modulation of the peak wavelength of the output.

As the skilled person will appreciate, one or more of the first wafer, the second wafer or components of the tunable laser can be provided by forming them during a manufacture process, using known techniques such as: metalorganic vapour-phase epitaxy (MOVPE), surface passivation, photolithography, ion implantation, etching, dry etching ion etching, wet etching, buffered oxide etching, plasma ashing, plasma etching, thermal treatment, annealing, thermal oxidation, chemical vapor deposition, atomic layer deposition, physical vapor deposition, molecular beam epitaxy, laser lift-off, electrochemical deposition, electroplating, or chemical-mechanical polishing. In some examples etching techniques are used to remove portions of material, as part of patterning, as the skilled person will appreciate. A person skilled in the art will appreciate the first wafer and the second wafer can be mechanically connected and/or optically connected using known techniques such as: wafer fusion, anodic bonding, adhesion. The skilled person will readily understand how to form an optical amplifier, an electro-optically tunable optical filter or a thermally tunable optical filer on a surface of a wafer.

A description of some terms and features used previously is now given, to elaborate on features of examples described herein.

A waveguide herein is for guiding light. Light propagates within a waveguide and is confined within a waveguide due to reflection at the boundaries of the waveguide. A waveguide usually has a refractive index greater than the refractive index of material in contact with the waveguide at the boundaries at which guiding of light is desired. In this manner, a waveguide guides the propagation of light. For light to propagate in the waveguide, it is desired that the light reflected at the boundaries of the waveguide fulfils the conditions for constructive interference. In some examples, the waveguide is at least one of: semiconductor junction or an electro-refractive modulator.

An optical amplifier is for increasing the power of an output of the tunable laser by amplifying light within the optical cavity. In some examples, light emitted from the tunable laser is spatially coherent and temporally coherent. In some examples, optical amplification is achieved by at least one of stimulated emission or spontaneous emission due to electron-hole recombination. The wavelength of light amplified by the optical amplifier may be between 10 nanometres and 1 millimetre. Examples of optical amplifiers include: solid-state amplifiers, doped-fibre amplifiers, semiconductor amplifiers, Raman amplifiers, or parametric amplifiers. An optical amplifier may comprise InGaAsP or aluminium indium gallium arsenide (AlInGaAs). Other optical amplifiers are envisaged. The optical amplifier may comprise an alloy of the first semiconductor material, for example, the optical amplifier comprises InGaAsP and the first semiconductor material is InP. This may simplify integration of the optical amplifier into the first wafer of the tunable laser, providing the first wafer comprising the optical amplifier, and/or forming the optical amplifier on the first wafer.

A resonator, a reflector, a partial reflector, or an interferometer may be used to provide at least one terminus of an optical cavity. A reflector may be a mirror. A resonator may be a ring resonator. An interferometer may be an MMI. In some examples a resonator comprises a ring along the circumference of which light propagates, the circumference of the ring such that a standing wave occurs when light is injected into the resonator. Other tunable resonators are envisaged such as a plane parallel resonator, a concentric resonator, a confocal resonator, a disc resonator, a toroidal resonator, or a hemispherical resonator.

A tunable resonator is a structure configured for optical modes within the tunable resonator to interfere causing constructive or destructive interference depending on an effective path length or effective path lengths within the structure and/or the wavelength of a mode or modes. In some examples the tunable resonator is a tunable ring resonator and comprises a ring waveguide structure. A tunable ring resonator may comprise two waveguides each with a first end optically connected to a first power coupler and a second end optically connected to a second power coupler (a power coupler is for example an MMI) to form a ring. The radius of a tunable ring resonator may be chosen to, for example, for mode selection. The waveguides of a tunable ring resonator may be curved to form a ring and, in some such examples the tunable ring resonator is not circular. By tuning an optical path length or a refractive index within the resonator in turn tunes the wavelength of the output spectrum of the tunable resonator.

An interferometer is for interfering a plurality of optical modes. A phase difference between the optical modes produces constructive interference or destructive interference. In some examples the interferometer is a Mach-Zehnder interferometer (MZI), such as an asymmetric MZI (AMZI). Other example interferometers are a Fizeau interferometer, a Fabry Perot interferometer, a Michelson interferometer, or a Lyot interferometer, other interferometers are envisaged. The phase difference between the optical modes may be tuned by tuning an optical path length or a refractive index within the interferometer in turn tunes the wavelength of a constructive interference or destructive interference in the in the interferometer which in turn tunes the output spectrum and/or power of the interferometer.

A free spectral range of a tunable optical filter is the wavelength separation between two successive reflected or transmitted power maxima of the tunable optical filter. In some examples, a free spectral range of the electro-optically tunable optical filter is different to a free spectral range of the thermally tunable optical filter, in other examples, the free spectral range of the electro-optically tunable optical filter is the same as the free spectral range of the thermally tunable optical filter. In some examples with a difference between the free spectral range of the electro-optically tunable optical filter and the free spectral range of the thermally tunable optical filter the output of the tunable laser may have a reduced linewidth. A linewidth herein is the full-width at half-maximum (FWHM) of a peak of the spectrum of the output of the tunable laser. The linewidth is, for example, at least one of: less than 100 kilohertz, less than 50 kilohertz, less than 20 kilohertz, less than 10 kilohertz, or less than 2 kilohertz.

A scanning speed of a tunable optical filter is the maximum rate at which a peak transmission wavelength of the tunable optical filter can be tuned, for example in nanometres per second. In some examples, a scanning speed of the electro-optically tunable optical filter is different to a scanning speed of the thermally tunable optical filter, and in other examples, the scanning speed of the electro-optically tunable optical filter is the same as the scanning speed of the thermally tunable optical filter. In some examples the electro-optically tunable optical filter is for modulating the wavelength of the output of the tunable laser. The scanning speed of the electro-optically tunable optical filter may be faster than the scanning speed of the thermo-optically tunable optical filter, for example, because electro-optic tuning requires less dissipation of heat than thermo-optic tuning. The faster scanning speed of the electro-optically tunable optical filter is, for example, for imaging or telecommunications applications. In some examples, the scanning speed of the electro-optically tunable optical filter is at least one of 100, 1000, 10000, 100000, or 1000000 times faster than the scanning speed of the thermally tunable optical filter. Electro-optic tuning may require less electrical power than thermo-optic tuning, e.g., for low-power devices or applications.

A low resonance FWHM may be provided by the thermally tunable optical filter, and/or fast modulation may be provided by the electro-optically tunable optical filter.

An optical cavity is an arrangement of optical elements as a cavity resonator for forming a standing light wave. An optical cavity may be provided by optically connecting the optical amplifier, the electro-optically tunable optical filter and the thermally tunable optical filter. An optical cavity comprises the optical amplifier, the electro-optically tunable optical filter and the thermally tunable optical filer.

An optical connection is, for example, the optically connected optical elements being configured such that light may propagate through free-space between the optically connected optical elements and/or the optically connected optical elements being optically connected by a waveguide such that light may propagate through the waveguide between the optically connected optical elements. The first wafer and the second wafer are, for example, optically connected by an optical element on the first wafer being optically connected to an optical element on the second wafer. As the skilled person will appreciate, optical as used herein refers to at least one of ultraviolet, visible, mid-infrared, infrared C-band, or infrared light.

A wafer referred to herein is, for example, a single layer of the same homogenous material, though it is envisaged for other examples that a wafer instead comprises one or more layers or portions each deposited or formed independently of each other (for example one after another during a manufacture process to form a stack of sub-layers which together could be considered a wafer). A wafer may comprise portions of different materials, for example for fabrication. In some examples at least one of the optical amplifier or the electro-optically tunable optical filter comprises InGaAsP. In some examples, at least one of: the electro-optically tunable optical filter and the optical amplifier comprise the first semiconductor material, or the thermally tunable optical filter comprises the second material. In some examples, at least one of the the second material or the third material described herein, comprises at least one of a semiconductor, a dielectric, or a polymer. In various examples, at least one of the first semiconductor material, the second material or the third material described herein, comprises at least one of Si, InP, gallium arsenide (GaAs), gallium antimonide (GaSb), gallium nitride (GaN), indium gallium arsenide (InGaAs), indium aluminium arsenide (InAlAs), indium aluminium gallium arsenide (InAlGaAs), AlGaAs, InGaAsP, SiN, silicon oxide (SiO2), tantalum pentoxide (Ta2O5 or tantala), aluminium oxide (Al2O3, or alumina), aluminium nitride (AIN) or LiNbO3. Other materials are envisaged in further examples.

It is to be understood that any feature described in relation to any one example may be used alone, or in combination with other features described, and may also be used in combination with one or more features of any other of the example, or any combination of any other of the examples. Furthermore, equivalents and modifications not described above may also be employed without departing from the scope of the accompanying claims.

Clause 1: A method of manufacturing a tunable laser comprising:
a first wafer of a first semiconductor material, supporting an optical amplifier and an electro-optically tunable optical filter; and
a second wafer of a second material different from the first semiconductor material, supporting a thermally tunable optical filter,
an optical cavity comprising the optical amplifier, the electro-optically tunable optical filter, and the thermally tunable optical filter, the method comprising:
providing the first wafer of the first semiconductor material supporting the optical amplifier and the electro-optically tunable optical filter;
   providing the second wafer of the second material supporting the thermally tunable optical filter;
optically connecting the first wafer to the second wafer such that the optical cavity of the tunable laser comprises the optical amplifier, the electro-optically tunable optical filter, and the thermally tunable optical filter.

Clause 2: A method of manufacturing a tunable laser comprising:
a first wafer of a first semiconductor material, supporting an optical amplifier and an electro-optically tunable optical filter; and
a second wafer of a second material different from the first semiconductor material, supporting a thermally tunable optical filter,
an optical cavity comprising the optical amplifier, the electro-optically tunable optical filter, and the thermally tunable optical filter, the method comprising:
providing the second wafer of the second material;
mechanically connecting the first wafer to the second wafer; and
forming the electro-optically tunable optical filter and the optical amplifier supported by the first wafer and forming the thermally tunable optical filter supported by the second wafer such that an optical cavity of the tunable laser comprises the optical amplifier, the electro-optically tunable optical filter, and the thermally tunable optical filter.

Clause 3: A method of manufacturing a photonic integrated circuit comprising the method of clause 1 or clause 2.

Clause 4: A method of manufacturing a device comprising the method of any of clauses 1 to 3.

Clause 5: The method of clause 4, comprising providing a controller configured for at least one of modulation of the power of the output of the tunable laser, or modulation of the peak wavelength of the output.

What is claimed is:

1. A tunable laser comprising:
a first wafer of a first semiconductor material, supporting an optical amplifier and an electro-optically tunable optical filter; and
a second wafer of a second material different from the first semiconductor material, supporting a thermally tunable optical filter,
an optical cavity comprising the optical amplifier, the electro-optically tunable optical filter, and the thermally tunable optical filter.

2. The tunable laser of claim 1, wherein at least one of:
the first wafer abuts the second wafer;
the first wafer is on the second wafer;
the first wafer supports the second wafer; or
the second wafer supports the first wafer.

3. The tunable laser of claim 1, wherein at least one of:
the electro-optically tunable optical filter, or
the thermally tunable optical filter, comprises a tunable resonator.

4. The tunable laser of claim 1, wherein at least one of:
the electro-optically tunable optical filter, or
the thermally tunable optical filter, comprises an interferometer.

5. The tunable laser of claim 1, wherein at least one of:
the electro-optically tunable optical filter, or
the thermally tunable optical filter, comprises an interferometer and a tunable resonator.

6. The tunable laser of claim 1, wherein a scanning speed of the electro-optically tunable optical filter is at least 1000 times faster than a scanning speed of the thermally tunable optical filter and a wavelength tuning range of the thermally tunable optical filter is 10 times greater than a wavelength tuning range of the electro-optically tunable optical filter.

7. The tunable laser of claim 1, wherein the free spectral range of the electro-optically tunable optical filter is different to the free spectral range of the thermally tunable optical filter.

8. The tunable laser of claim 1, wherein at least one of:
the first semiconductor material comprises indium phosphide, or the second material comprises silicon.

9. The tunable laser of claim 1, wherein the optical cavity is a linear optical cavity.

10. The tunable laser of claim 1, wherein the first wafer or the second wafer is a substrate for a photonic integrated circuit, or the first wafer and the second wafer are supported by a substrate for a photonic integrated circuit.

11. The tunable laser of claim 1, wherein at least one of:
the electro-optically tunable optical filter and the optical amplifier comprise the first semiconductor material, or
the thermally tunable optical filter comprises the second material.

12. A photonic integrated circuit comprising a tunable laser comprising:
a first wafer of a first semiconductor material, supporting an optical amplifier and an electro-optically tunable optical filter; and
a second wafer of a second material different from the first semiconductor material, supporting a thermally tunable optical filter,
an optical cavity comprising the optical amplifier, the electro-optically tunable optical filter, and the thermally tunable optical filter.

13. The photonic integrated circuit of claim 12, wherein at least one of:
the first wafer abuts the second wafer;
the first wafer is on the second wafer;
the first wafer supports the second wafer; or
the second wafer supports the first wafer.

14. The photonic integrated circuit of claim 12, wherein at least one of:
the electro-optically tunable optical filter, or
the thermally tunable optical filter, comprises a tunable resonator.

15. The photonic integrated circuit of claim 12, wherein at least one of:
the electro-optically tunable optical filter, or
the thermally tunable optical filter, comprises an interferometer.

16. A device comprising a photonic integrated circuit comprising a tunable laser comprising:
a first wafer of a first semiconductor material, supporting an optical amplifier and an electro-optically tunable optical filter; and
a second wafer of a second material different from the first semiconductor material, supporting a thermally tunable optical filter,
an optical cavity comprising the optical amplifier, the electro-optically tunable optical filter, and the thermally tunable optical filter.

17. The device of claim 16, comprising a controller configured for at least one of modulation of the power of the output of the tunable laser, or modulation of the peak wavelength of the output.

18. The device of claim 16, wherein at least one of:
the first wafer abuts the second wafer;
the first wafer is on the second wafer;
the first wafer supports the second wafer; or
the second wafer supports the first wafer.

19. The device of claim 16, wherein at least one of:
the electro-optically tunable optical filter, or
the thermally tunable optical filter comprises a tunable resonator.

20. The device of claim 16, wherein at least one of:
the electro-optically tunable optical filter, or
the thermally tunable optical filter, comprises an interferometer.
